(19) United States
(12) Patent Application Publication
(10) Pub. No.: US 2008/0018556 A1
(43) Pub. Date: Jan. 24, 2008

(54) Method for Micropackaging of Leds and Micropackage

(76) Inventor: John Gregory, Atlanta, GA (US)

Correspondence Address: KOPPEL, PATRICK & HEYBL, 555 ST. CHARLES DRIVE, SUITE 107, THOUSAND OAKS, CA, 91360, US

(21) Appl. No.: 11/575,910

(22) PCT Filed: Sep. 28, 2005
(86) PCT No.: PCT/US05/34894

§ 371 Date: Jun. 5, 2007

Related U.S. Application Data
(60) Provisional application No. 60/614,323, filed on Sep. 28, 2004.
(60) Provisional application No. 60/614,763, filed on Sep. 30, 2004.

(51) Int. Cl. G09G 3/14; H01L 33/00

(52) U.S. Cl. 345/46; 257/88; 257/99; 438/26; 257/E33.058

(57) ABSTRACT

A micropackage including a substrate composed of a flexible plastic material having laminated on opposite sides thereof films of a conductive metal. A cavity is formed in the substrate with the laminated film on a first side having at least one tab projecting into the cavity. An LED having a first contact is positioned in the cavity of the substrate with the tab bonded to the first contact. The LED has a second contact that is bonded to one of the film on the opposite, second side of the substrate and a second tab defined by the film on the first side of the substrate. A dome of transparent material is adhered to the first side of the substrate covering the LED on the first side of the substrate. A method for making the micropackage. A data display using the micropackage, and a method of making the data display.

### BACKGROUND OF THE INVENTION

1. Field of the Invention

The invention relates to a method for micropackaging LEDs and a micropackage including an LED. More particularly, the invention relates to a method for micropackaging LEDs and forming a data display, wherein the LED is embedded in a flexible plastic substrate and further relates to a micropackage that has such an LED embedded in a flexible plastic substrate, and to a data display.

2. Prior Art

In the past, LEDs have been package by surface mounting the devices using wire bonding or flip chip technology. Since the LED component is rigid chip, if surface mounted on a flexible substrate, there is a danger that the component or one or more of the connections to the flexible substrate will pop-off or disconnect when the substrate is flexed.

### SUMMARY OF THE INVENTION

Accordingly, the principal object of the present invention is to provide a method and device that solves the above disadvantage of the prior art. Therefore the present invention provides a method for micropackaging LED devices on a flexible substrate, and a micropackage including a flexible substrate that will not pop-off or lose connections when the substrate is flexed.

The above is achieved by a novel method for micropackaging that embeds an electrical or electro mechanical device in a flexible plastic substrate, and by a micropackage that has the device embedded in a flexible plastic substrate. The embedding of the device or component in the flexible substrate will enhance the procedure for making data displays that are planar and small and thin.

A further object of the invention is to provide a micropackage comprising:
a. a substrate composed of a flexible plastic material having laminated on opposite sides thereof films of a conductive metal;
b. cavity formed in the substrate with the laminated film on one side having at least one tab projecting into the cavity;
c. an LED having a first contact positioned in the cavity of the substrate with the tab bonded to the first contact;
d. the LED having a second contact bonded to one of the film on the opposite side of the substrate and a second tab defined by the film on said one side of the substrate; and
e. a dome of transparent material adhered to the one side of the substrate covering the LED on the said one side of the substrate.

As further objects of the invention, the micropackage according to the above can be arranged wherein the LED is an axial LED and the top of the LED emanates light through the dome, and the bottom of the LED is bonded to the film on the opposite side of the substrate. Also, the micropackage can have the bond to the film on the opposite side of the substrate is Ag solder.

Where the LED is a linear LED, the second tab is bonded to a contact on the LED, and the top film is separated into two interconnects, one coupled to each tab. Preferably, the films are copper, and are from about 12 to about 20 microns thick. White reflective enamel can be coated on the opposite side of the substrate over the LED. A second dome of transparent material can be adhered to the opposite side of the substrate over the LED. The dome can include light dispersing particles.

A further object of the invention is to provide a digital or data display comprising a substrate having embedded therein, for each numeral, a plurality of LEDs arranged in an array defining a numeral pattern with a masking material over the substrate defining enlarged openings associated above the LEDs, substantially larger than its associated LED, each associated opening filled with a doming material to form a slightly elliptical lens over the associated LED and spread the light emanating from the LED over a wider area, the substrate having laminated thereto conductive films that define circuitry coupled to the LEDs to power the LEDs.

As a still further object of the invention the digital or data display can be fashioned from either axial LEDs or linear LEDs. Also, the circuitry can address the LEDs of each numeral separately with a common ground, or the circuitry can address all corresponding LEDs of all numerals in series with a separate ground for each numeral. Still further, where the LEDs are linear, vias couple the conductive film of one side acting as a ground interconnect to the other side acting as a ground plane.

Another object of the present invention is to provide a method of making a micropackage comprising the steps of:
a. providing a substrate composed of a flexible plastic material having laminated on opposite sides thereof films of a conductive metal;
b. forming a cavity in the substrate with the laminated film on one side having at least one tab projecting into the cavity;
c. positioning an LED having a first and second contact in the cavity of the substrate with the tab bonded to the first contact;
d. bonding the second contact of the LED to one of the film on the opposite side of the substrate and a second tab defined by the film on said one side of the substrate; and
e. adhering a dome of a transparent material to the one side of the substrate covering the LED on the said one side of the substrate.

The method of making a micropackage according to the above can be arranged wherein the LED is an axial LED and the top of the LED emanates light through the dome, and the bottom of the LED is bonded to the film on the opposite side of the substrate. The films are copper from about 12 to about 20 microns thick. Still another object of the invention is to provide a method of making a digital or data display comprising the steps of:
a. embedding a plurality of LEDs arranged in an array defining a numeral pattern in a substrate having conductive films on opposite sides;
b. covering the numeral pattern in the substrate with a masking material;
c. forming enlarged openings associated above the LEDs, each opening substantially larger than its associated LED;
d. filling each associated opening with a doming material to form a slightly elliptical lens over the associated LED to spread the light emanating from the LED over a wider area;
e. enabling coupling circuitry defined by conductive films laminated on the substrate to the LEDs to power the LEDs.

The foregoing method can be arranged wherein the circuitry addresses the LEDs of each numeral separately with a common ground, or wherein the circuitry addresses all corresponding LEDs of all numerals in series with a separate ground for each numeral.

Other and further objects and advantages will become apparent from the following detailed description of embodiments of the invention when taken together with the appended drawings as described below.

### BRIEF DESCRIPTION OF THE DRAWINGS

FIGS. 1A to E show schematically the mounting of an axial LED in a micropackage according to the present invention;

FIGS. 2A to F show schematically the mounting of a linear LED in a micropackage according to the present invention;

FIGS. 3A to C show schematically and illustrate the mounting of an LED in a data display;

FIG. 4 shows schematically the format of a digit in the novel data display;

FIGS. 5A to C show schematically, the doming of the LED in the data display;

FIGS. 6A to F show two versions of axial LED arrays for the novel data display; and

FIG. 7A F show two versions of linear LED arrays for the novel data display;

### DETAILED DESCRIPTION OF PREFERRED EMBODIMENTS OF THE INVENTION

Essentially, the method of the present invention consists of providing an interconnect for an LED to a flexible substrate that could serve as an interposer to connect the LED mounted on the first flexible substrate to a second flexible substrate. The mounting of the LED to a flexible substrate is achieved by ultra sonically bonding a circuit interconnect to the LED by employing a method of embedding the LED in a substrate as described in WO 01/65595 A2, the contents of which are herein incorporated by reference in their entirety. This method consists essentially of providing a flexible dielectric substrate laminated with a conductive foil, preferably copper, on opposite sides of the substrate. First, an interconnecting conductive circuit is created on the top side of the laminated dielectric substrate by selectively removing portions of the conductive foil using known photo-imaging techniques to leave remaining an interconnecting conductive circuit projecting in part (one tab if an axial LED is to be mounted, and two tabs if a linear LED is to be mounted) into the perimeter of a preselected volume of the dielectric substrate material. Then, using photo-imaging techniques, the conductive foil from the bottom side of the laminated dielectric substrate is photo-imaged and removed within the perimeter of the preselected volume to expose the dielectric substrate material within the said perimeter. Thus, there are two tabs on the top side for a linear LED mounting, and one tab on the top side projecting into the cavity to be formed for an axial LED mounting. Next, the volume of the dielectric substrate material within said perimeter is removed by laser ablation to create a cavity or void in the dielectric substrate material without destroying the parts of the interconnecting conductive circuit projecting into the perimeter of the void. Then, an electronic component (LED) is inserted into the void, preferably, having a thickness not greater than the preselected thickness of the laminated dielectric substrate (axial LEDs tend to be thicker than the substrate and therefore, will project). At least one contact will correspond in position to the part (tab) of said interconnecting conductive circuit that project into the perimeter of the void so that when fully inserted, the contact on the electronic component registers with and contacts said projecting part (tab) of the interconnecting conductive circuit. As noted, for a linear LED, there will be two tabs projecting into the cavity or void. Finally, the contact(s) on the electronic component (LED) and the projecting part(s) of the interconnecting conductive circuit on the top side is (are) bonded together (preferably by ultrasonic bonding) to hold the electronic component in the cavity or void of the dielectric substrate material. In the case of an axial LED, the bottom side of the substrate has Ag solder applied to fixed and provide an electrical contact to the bottom of the axial LED to the bottom conductive film of the substrate.

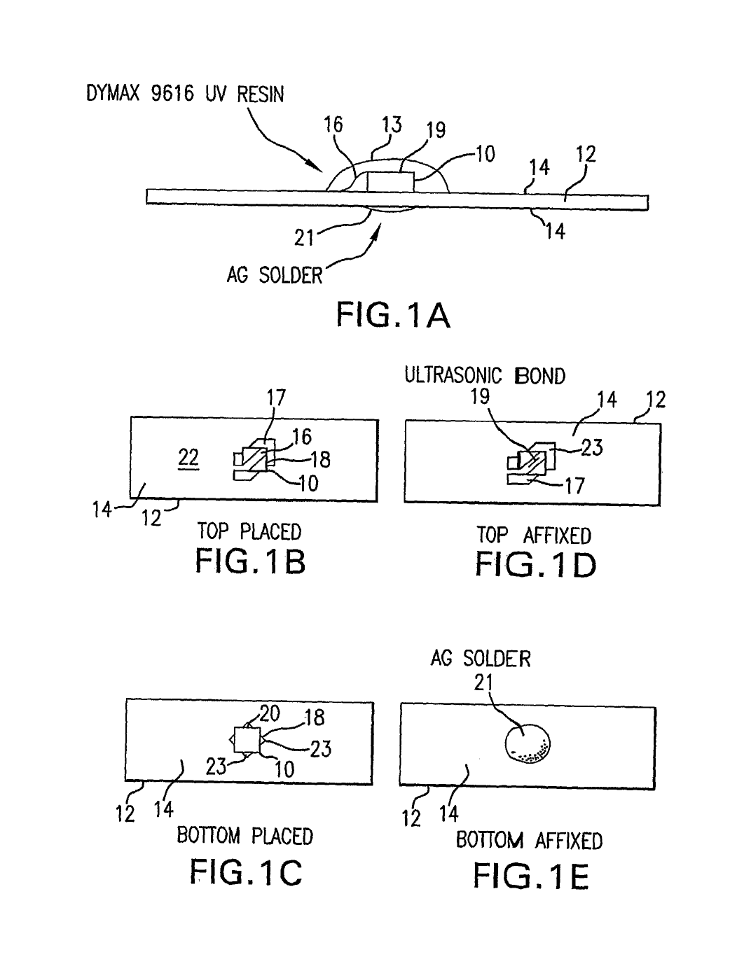

FIGS. 1A to E illustrate a mounting of an axial LED 10 to a substrate 12, with the mounting manufactured in the above-described manner which results in an electrical connection on the top side which is 18 microns in thickness. As shown, a flexible substrate 12 composed of a dielectric material, such as, PET or LCP or other suitable dielectric plastic material, with copper films 14 laminated on the top and bottom sides, has embedded therein (in a cavity or void 17) a LED 10 interconnected by top and tab 16, formed from the copper film 14 laminated on the top side. The tab 16 on the top surface is ultrasonically bonded at 19 to the top contact 18 on the LED 10. The bottom contact 18 of the LED 10 is fixed by a Ag solder 21 that connects the bottom of the LED 10 with the copper film 14 laminated to the bottom of the substrate. A doming transparent epoxy 13, such as DYMAX 9616, made by the Dymax Corporation of Torrington, Conn., covers the LED 10

Whereas the cavity 17 created by laser ablation has to be at least the complementary size and shape of the chip 10, it is preferably made slightly larger (see reference numeral 20) than the chip 10 to provide a small relief 23 at the sides. The tab 16 is part of the interconnect circuit 22 which is the power side of the LED. The bottom film 14 serves as the ground. The top and bottom copper films can be from 12 to 20 microns thick. Preferably the films 14 are composed of ½ oz copper and about 18 microns thick. If the arrangement is to form an interposer, the copper films 14 can extend out over the ends of the dielectric substrate 12 to form flanges, which flanges can be bonded (e.g. ultrasonic bonding or soldering) to contacts or connections of an electrical circuit on a PCB or other second substrate that the interposer is mounted to. The circuit contacts or connections on the PCB or other substrate are preferably copper.

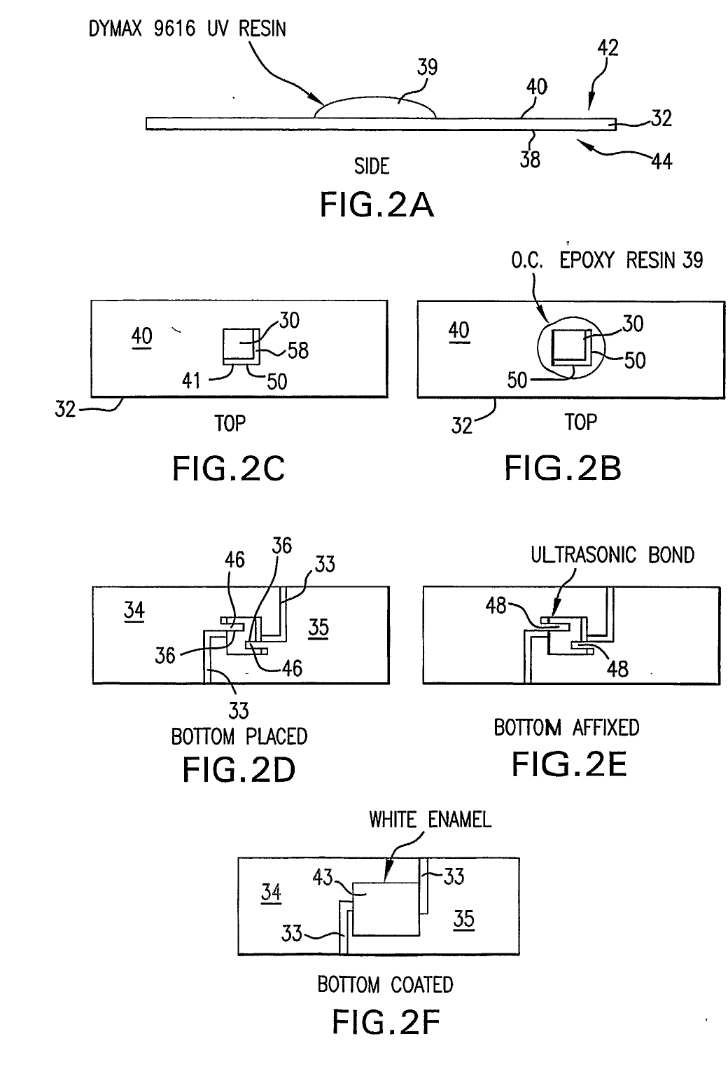

FIGS. 2A to F illustrate a mounting of a linear LED 30 to a substrate 32 in a cavity or void, with the mounting manufactured in the above-described manner which results in electrical interconnects 34, 35, formed in the bottom film 38, which is 18 microns in thickness, to the contacts 36 of the linear LED 30 on the bottom side 38, the chip being inserted, contact side down into the cavity from the top. The interconnects 34, 35 (interconnect 34 serves as the power connect, and interconnect 35 serves as the ground connect) are separated by two channels 33 by photo-imaging so that exposed dielectric material of the substrate 32 separates them. The top side film 40, also 18 microns thick, can serve as a ground plane as will be explained hereinafter. As shown, a flexible substrate 32 composed of a dielectric material, such as, PET or LCP or other suitable dielectric plastic material, with copper films 40, 38 laminated on the top and bottom sides 42, 44, has embedded therein, in a cavity or void 41, a linear LED 30 interconnected by tabs 46, formed from the copper film 38 laminated on the bottom side 44. The two tabs 46 on the bottom side of the substrate, one projecting from each interconnect are ultrasonically bonded at 48 to the contacts 36 on the LED 30. The LED will emanate light from both the top and the bottom. The bottom of the LED 30 is coated with a white reflective enamel coating 43 to reflect the light through the top and to provide a continuous surface with the copper film 38 laminated to the bottom of the substrate 32. A transparent doming epoxy 39, as described above, is placed on the top film 40 over the chip 30 and has a diameter substantially greater than the width of the chip to spread out the light emanating from the chip. If desired, a similar doming can be placed on the bottom of the substrate instead of the reflective white enamel, if it is desired to emanate light out both the top and the bottom.

Whereas the cavity or void 41 created by laser ablation has to be at least the complementary size and shape of the chip 30, it is preferably made slightly larger (see reference numeral 50) than the chip 30 by about 12 microns on two adjacent sides and is provided with small relief recesses 52 at the corners. Interconnect 35 can be connected by vias to the top film 40 to serve as a ground plane. The vias can be drilled, lasered or punched holes that are filled with either copper or conductive ink to electrically couple the interconnect 35 to top film 40.

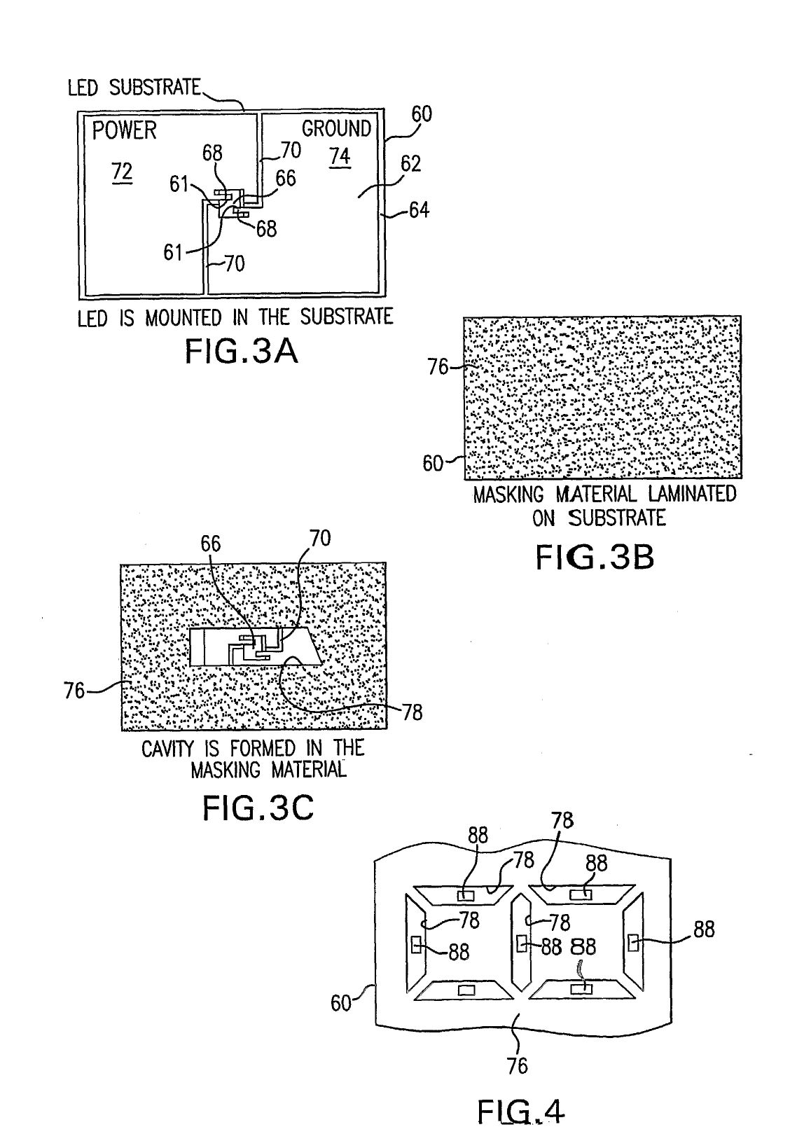

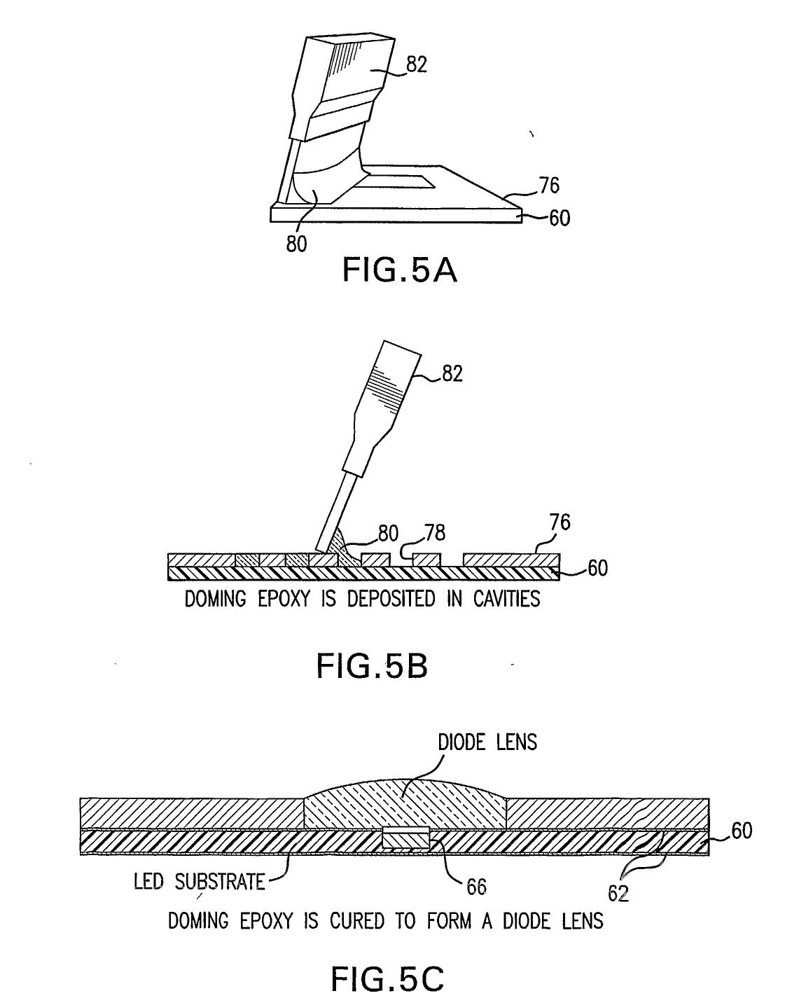

Referring now to FIGS. 3A to C and FIG. 4, the forming of a segment and a digit of a data display will now be described. A segment consists of only the mounting of a single LED, and it should be understood that the method involves replicating the mounting for all LEDs (segments), and then assembling into a data display, or alternatively, forming all segments and/or digits together. As shown in FIGS. 3A to C, a substrate 60, as described, is provided with conductive copper films 62 top and bottom. The films 62 are setback from the edges 64 of the substrate 60 by a small amount. A linear LED 66 is mounted contacts 61 up near the center of the substrate using tabs 68 formed from the bottom film 62 as described. The tabs 68 are ultrasonically bonded to the contacts 61 on the LED, as described. Channels 70 are formed in the top film 62 to individuate the power interconnect 72 and the ground interconnect 74. Next, the substrate with the LED mounted is covered with a masking material 76 and photo-imaged to make an enlarged opening 78 surrounding the LED in order to be able to spread out the light emanating from the LED. The enlarged opening 78, which can be of trapezoidal shape, is filled with a transparent or translucent lens material, such as an epoxy as produced and sold by Dymax Corporation of Torrington, Conn., e.g. DYMAX 9616 epoxy. The manner in which this is done is shown in FIGS. 5A to C. The lens material 80 is placed in mass on the substrate and spread by squeegee 82 over the substrate, filling the enlarged holes 78, each hole 78 representing a segment of a seven-segment digit of a data display, e.g. a six digit display. The data display is produced from a single substrate in which has embedded therein an array of LEDs using the pattern shown in FIG. 4, i.e. seven diodes 88 arranged in the pattern shown in the figure, with an enlarged hole or opening 78 over each diode 88, with six such digits arranged side-by-side. Alternatively, the digits can be made from individual substrates with only one digit per substrate and the six substrates arrayed together in a suitable frame.

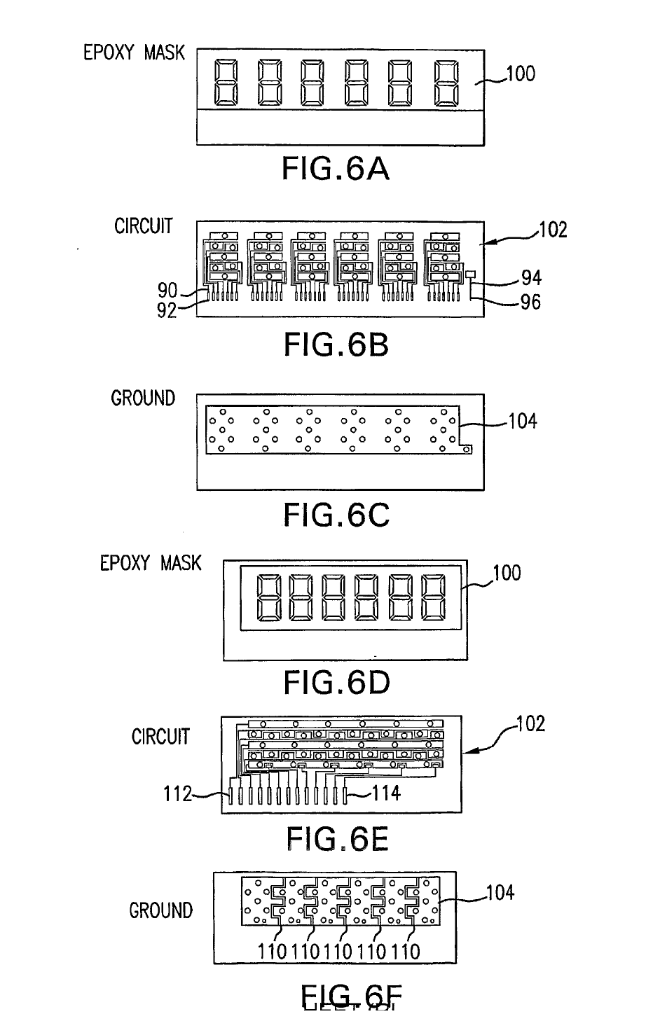

Shown in FIGS. 6A to F are two versions of a six digit or numeral display, each digit consisting of seven segments as described, using axial LEDs. The first version shown in FIGS. 3A to C uses a large spacing between digits and can be fashioned using six individual substrates set in a suitable frame or only one substrate with sufficient spacing between digits. The diodes in this version are addressed separately as shown by the leads 90 and interconnects or contacts 92 whereas the ground is a single lead 94 and interconnect or contact 96. FIG. 6A shows the epoxy mask 100, FIG. 6B shows the interconnections 102, as described, and FIG. 6C shows the ground plane 104. In the second version shown in FIGS. 6D to F, the corresponding diodes in each digit are addressed in series and the grounds for the diodes are separated by digit by dielectric channels 110 on the ground plane, photo-imaged as described for channels 70. Thus, the addressing of particular diodes is a combination of connecting the necessary segment contacts 112 and the appropriate ground contacts 114.

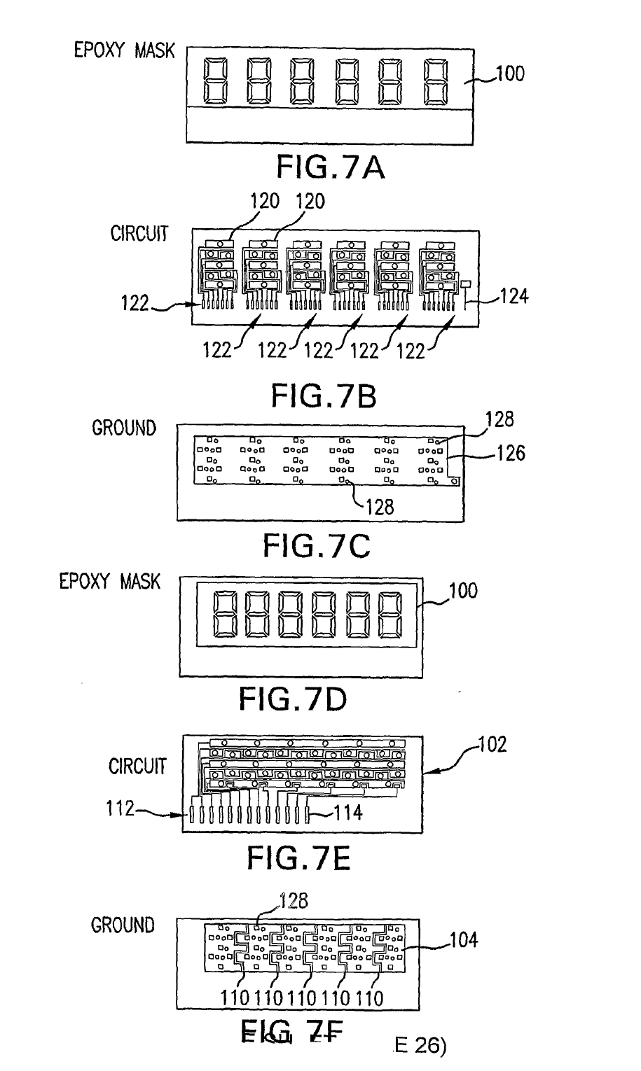

Shown in FIGS. 7A to F are two versions of a six digit or numeral display, each digit consisting of seven segments as described, using linear LEDs. The first version is like the first version of the axial LEDs. That is, the digits are separated and the circuitry connecting the diodes 120 is individuated between the six digits, as shown, leading to leads and contacts 122, a set for each digit. A single ground contact 124 is used connected to the ground plane 126. In this case, however, it is necessary to use vias 128 to connect the ground interconnects on the substrate to the opposite side of the substrate, as described. The second version is similar to the second version of the axial LEDs, and like reference numerals have been used. As in the first version of linear LEDs, vias 128 are necessary to couple the ground interconnects to the bottom ground plane.

Summarizing, the invention provides a method for manufacturing an optical lens with a unique shape which will enhance the illuminating characteristic of a light emitting diode. In the past a light emitting diode as a single source of light was in conventional applications encapsulated in a dome of optically clear or tinted epoxy to protect the diode and radiate the light emission from the component. The encapsulating dome added unacceptable height or a radiant characteristic to the diode which was not desirable. The present invention provides a method for creating an LED lens that reduces the height of the dome and affords the capability to create a unique radiating lens shape.

According to the inventive method, an LED is mounted in substrate material which has a conductive layer of copper or similar electrical current carrying metal on each side of the substrate. The diode is affixed in the substrate and connected to the power and ground planes resident on the substrate by employing a novel assembly technique. Having assembled the LED device in this manner, the diode may be illuminated by introducing electrical current to the power and ground terminals. Upon the surface of the LED substrate is laminated a photo-imagable material. When the photo imaged material is processed, the thickness of the material is sufficient to form a cavity around the light emitting diode in a unique shape. The cavity will have a pre-determined volume based on the height, length and width of the cavity.

A commercially available doming material (epoxy) is deposited in the cavities of the masking material. A reservoir of material is deposited on the edge of the substrate and by drawing the doming material into the cavities of the masking layer using an implement with a flat edge; the cavities are filled with the lens material.

Prior to depositing the doming epoxy in the cavities, finely granulated silicate particles may be added to enhance light refraction and diffusion.

Prior to depositing the doming material in the cavities, phosphor material may be added to the doming epoxy to change the radiating spectrum of the diode.

When the deposition of the doming epoxy is completed the material is cured by exposing to ultra violet light or some materials may require a thermal cure. The doming material swells slightly during the curing process to form an elliptical surface which radiates light from the diode.

The invention also contemplates a display device with optical lens with a unique shape which will enhance the illuminating characteristic of light emitting diodes incorporated in the display device.

A light emitting diode is a single source of light which in conventional applications is encapsulated in a dome of optically clear or tinted epoxy which protects the diode and radiates the light emission from the component. The encapsulating dome may add height or a radiant characteristic to the diode which is not desirable. The display device of the invention uses an LED lens that reduces the height of the dome and affords the capability to create a unique radiating lens shape.

A series of 6 to 8 LEDs are mounted in substrate material which has a conductive layer of copper or similar electrical current carrying metal on each side of the substrate. The diodes are affixed in the substrate and connected to the power and ground planes resident on the substrate by employing a novel assembly technique, see International Patent Application Publication WO 01/65595 A2. Having assembled the display device in this manner, the diodes may be illuminated by introducing electrical current to the power and ground terminals.

Upon the surface of the substrate is laminated a photo-imagable material. When the photo-imaged material is processed, the thickness of the material is sufficient to form cavities around the light emitting diodes in a unique shape. The cavities will have a pre-determined volume based on the height, length and width of the cavities. A commercially available doming material (epoxy) is deposited in the cavities of the masking material. A reservoir of material is deposited on the edge of the substrate and by drawing the doming material into the cavities of the masking layer using an implement with a flat edge, the cavities are filled with the lens material.

Prior to depositing the doming epoxy in the cavities, finely granulated silicate particles may be added to enhance light refraction and diffusion.
Prior to depositing the doming material in the cavities, phosphor material may be added to the doming epoxy to change the radiating spectrum of the diode. When the deposition of the doming epoxy is completed the material is cured by exposing to ultra violet light or some materials may require a thermal cure. The doming material swells slightly during the curing process to form an elliptical surface for each cavity, which radiates the light from the diode mounted in the cavity. Although the invention has been shown and described with respect to specific embodiments, changes and modifications are possible without departing from the inventive concepts as expressed in the claims. Such changes and modifications are deemed to fall within the purview of the invention as claimed.

What is claimed is:

1. A micropackage comprising:
a. a substrate composed of a flexible plastic material having laminated on opposite sides thereof films of a conductive metal;
b. a cavity formed in the substrate with the laminated film on one side having at least one tab projecting into the cavity;
c. an LED having a first contact positioned in the cavity of the substrate with the tab bonded to the first contact;
d. the LED having a second contact bonded to one of the film on the opposite side of the substrate and a second tab defined by the film on said one side of the substrate; and
e. a dome of transparent material adhered to the one side of the substrate covering the LED on the said one side of the substrate.

2. A micropackage according to claim 1 wherein the LED is an axial LED and the top of the LED emanate light through the dome, and the bottom of the LED is bonded to the film on the opposite side of the substrate.

3. A micropackage according to claim 2 wherein the bond to the film on the opposite side of the substrate is Ag solder.

4. A micropackage according to claim 1 wherein the LED is a linear LED and the second tab is bonded to a contact on the LED, and the top film is separated into two interconnects, one coupled to each tab.

5. A micropackage according to claim 1 wherein the films are copper.

6. A micropackage according to claim 5 wherein the films are from about 12 to about 20 microns thick.

7. A micropackage according to claim 4 wherein white reflective enamel is coated on the opposite side of the substrate over the LED.

8. A micropackage according to claim 1 wherein a second dome of transparent material is adhered to the opposite side of the substrate over the LED.

9. A micropackage according to claim 1 wherein the dome includes light dispersing particles.

10. A digital or data display comprising a substrate having embedded therein, for each numeral, a plurality of LEDs arranged in an array defining a numeral pattern with a masking material over the substrate defining enlarged openings associated above the LEDs, substantially larger than its associated LED, each associated opening filled with a doming material to form a slightly elliptical lens over the associated LED and spread the light emanating from the LED over a wider area, the substrate having laminated thereto conductive films that define circuitry coupled to the LEDs to power the LEDs.

11. A digital or data display according to claim 10 wherein the LEDs are one of axial LEDs and linear LEDs.

12. A digital or data display according to claim 10 wherein the circuitry addresses the LEDs of each numeral separately with a common ground.

13. A digital or data display according to claim 10 wherein the circuitry addresses all corresponding LEDs of all numerals in series with a separate ground for each numeral.

14. A digital or data display according to claim 10 wherein the LEDs are linear, and vias couple the conductive film of one side acting as a ground interconnect to the conductive film of the other side serving as a ground plane.

15. A method of making a micropackage comprising the steps of:
a. providing a substrate composed of a flexible plastic material having laminated on opposite sides thereof films of a conductive metal;
b. forming a cavity in the substrate with the laminated film on one side having at least one tab projecting into the cavity;
c. positioning an LED having a first and second contact in the cavity of the substrate with the tab bonded to the first contact;
d. bonding the second contact of the LED to one of the film on the opposite side of the substrate and a second tab defined by the film on said one side of the substrate; and
e. adhering a dome of a transparent material to the one side of the substrate covering the LED on the said one side of the substrate.

16. A method of making a micropackage according to claim 15 wherein the LED is an axial LED and the top of the LED emanates light through the dome, and the bottom of the LED is bonded to the film on the opposite side of the substrate.

17. A method of making a micropackage according to claim 15 wherein the films are copper from about 12 to about 20 microns thick.

18. A method of making a digital or data display comprising the steps of:
a. embedding a plurality of LEDs arranged in an array defining a numeral pattern in a substrate having conductive films on opposite sides;
b. covering the numeral pattern in the substrate with a masking material;
c. forming enlarged openings associated above the LEDs, each opening substantially larger than its associated LED;
d. filling each associated opening with a doming material to form a slightly elliptical lens over the associated LED to spread the light emanating from the LED over a wider area;
e. enabling coupling circuitry defined by conductive films laminated on the substrate to the LEDs to power the LEDs.

19. A method according to claim 18 wherein the circuitry addresses the LEDs of each numeral separately with a common ground.

20. A method according to claim 18 wherein the circuitry addresses all corresponding LEDs of all numerals in series with a separate ground for each numeral.
